(19) United States
(12) Patent Application Publication
(10) Pub. No.: US 2023/0324968 A1
(43) Pub. Date: Oct. 12, 2023

(54) COOLING CAPABILITY DEGRADATION DIAGNOSIS IN AN INFORMATION HANDLING SYSTEM

(71) Applicant: Dell Products L.P., Round Rock, TX (US)

(72) Inventors: Xin Zhi Ma, Shanghai (CN); Yuan Chen, Shanghai (CN); Ying Hua Huang, Shanghai (CN); Wangchun Yao, Shanghai (CN); Pan Zou, Shanghai (CN)

(21) Appl. No.: 17/738,143

(22) Filed: May 6, 2022

(30) Foreign Application Priority Data
Apr. 8, 2022 (CN) 202210370988.5

(51) Int. Cl. G06F 1/20; H05K 7/20; H02P 7/29

(52) U.S. Cl. CPC G06F 1/206; G06F 1/203; H05K 7/20209; H02P 7/29

(57) ABSTRACT

An information handling system includes a memory and a processor. The memory stores data associated with cooling fans and other components within the information handling system. The processor receives a first set of data for a baseline cooling condition within the information handling system, and a second set of data for a current cooling condition. The processor determines whether a first subset of data in the first set of data is substantially equal to a second subset of data in the second set of data. If so, the processor determines whether a baseline device temperature is substantially equal to a current device temperature. If not, the processor determines a first degradation issue within the information handling system based on cooling fans in a first fan zone are operating at full speed, and both a first device temperature increases and a downstream components temperature increase.

### FIELD OF THE DISCLOSURE

The present disclosure generally relates to information handling systems, and more particularly relates to a cooling capability degradation diagnosis in an information handling system.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An information handling system includes a that may store data associated with cooling fans, temperature sensors, and components within the information handling system. A processor may store a first set of data for a baseline cooling condition within the information handling system. The processor further may receive a second set of data for a current cooling condition within the information handling system. The processor may determine whether a first subset of data in the first set of data is substantially equal to a second subset of data in the second set of data. In response to the first subset of data being substantially equal to the second subset of data, the processor may determine whether a baseline device temperature is substantially equal to a current device temperature. In response to the baseline device temperature not being substantially equal to the current device temperature, the processor may determine a first degradation issue within the information handling system based on cooling fans in a first fan zone for a first component are operating at full speed, and both a first device temperature increases and downstream components temperature increase.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of an information handling system according to an embodiment of the present disclosure;

FIG. 2 is a block diagram of a portion of an information handling system according to at least one embodiment of the present disclosure;

FIG. 3 is a flow diagram of method for calculating an airflow blockage percentage within an information handling system according to at least one embodiment of the present disclosure;

FIG. 4 shows multiple waveforms associated with a cooling fan within an information handling system according to at least one embodiment of the present disclosure;

FIG. 5 shows multiple waveforms representing a thermal resistance in cooling fans based on a pulse width modulate signal and an amount of dust within an information handling system according to at least one embodiment of the present disclosure; and

FIG. 6 is a flow diagram of method for determining one or more cooling degradation issues within an information handling system according to at least one embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings, and is provided to assist in describing the teachings. This focus should not be interpreted as a limitation on the scope or applicability of the teachings.

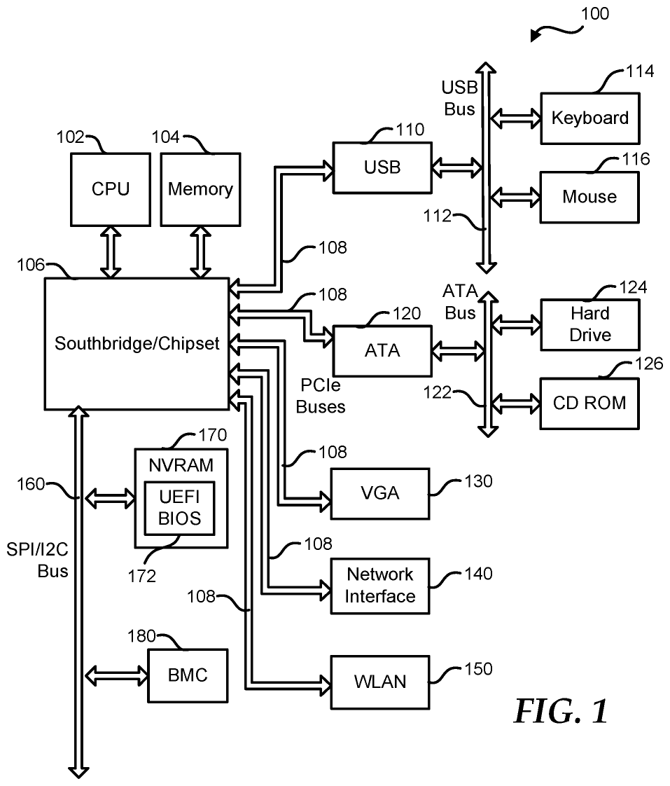

FIG. 1 illustrates an information handling system 100 according to at least one embodiment of the disclosure. For purpose of this disclosure information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system can be a personal computer, a laptop computer, a smart phone, a tablet device or other consumer electronic device, a network server, a network storage device, a switch, a router, or another network communication device, or any other suitable device and may vary in size, shape, performance, functionality, and price.

Information handling system 100 includes a processor 102, a memory 104, a chipset 106, a PCI bus 108, a universal serial bus (USB) controller 110, a USB 112, a keyboard device controller 114, a mouse device controller 116, a configuration database 118, an ATA bus controller 120, an ATA bus 122, a hard drive device controller 124, a compact disk read only memory (CD ROM) device controller 126, a video graphics array (VGA) device controller 130, a network interface controller (MC) 140, a wireless local area network (WLAN) controller 150, a serial peripheral interface (SPI) bus 160, a flash memory device 170 for storing UEFI BIOS code 172, a trusted platform module (TPM) 180, and a baseboard management controller (EC) 190. EC 190 can be referred to as a service processor, and embedded controller, and the like. Flash memory device 170 can be referred to as a SPI flash device, BIOS non-volatile random access memory (NVRAM), and the like. EC 190 is configured to provide out-of-band access to devices at information handling system 100. As used herein, out-of-band access herein refers to operations performed without support of CPU 102, such as prior to execution of UEFI BIOS code 172 by processor 102 to initialize operation of system 100. In an embodiment, system 100 can further include a platform security processor (PSP) 174 and/or a management engine (ME) 176. In particular, an x86 processor provided by AMD can include PSP 174, while ME 176 is typically associated with systems based on Intel x86 processors.

PSP 174 and ME 176 are processors that can operate independently of core processors at CPU 102, and that can execute firmware prior to the execution of the BIOS by a primary CPU core processor. PSP 174, included in recent AMD-based systems, is a microcontroller that includes dedicated read-only memory (ROM) and static random access memory (SRAM). PSP 174 is an isolated processor that runs independently from the main CPU processor cores. PSP 174 has access to firmware stored at flash memory device 170. During the earliest stages of initialization of system 100, PSP 174 is configured to authenticate the first block of BIOS code stored at flash memory device 170 before releasing the x86 processor from reset. Accordingly, PSP 174 provides a hardware root of trust for system 100. ME 176 provides similar functionality in Intel-based systems. In another embodiment, EC 190 can provide aspects of a hardware root of trust. The root of trust relates to software processes and/or hardware devices that ensure that firmware and other software necessary for operation of an information handling system is operating as expected.

Information handling system 100 can include additional components and additional busses, not shown for clarity. For example, system 100 can include multiple processor cores, audio devices, and the like. While a particular arrangement of bus technologies and interconnections is illustrated for the purpose of example, one of skill will appreciate that the techniques disclosed herein are applicable to other system architectures. System 100 can include multiple CPUs and redundant bus controllers. One ore more components can be integrated together. For example, portions of chipset 106 can be integrated within CPU 102. In an embodiment, chipset 106 can include a platform controller hub (PCH). System 100 can include additional buses and bus protocols, for example I2C and the like. Additional components of information handling system 100 can include one or more storage devices that can store machine-executable code, one or more communications ports for communicating with external devices, and various input and output (I/O) devices, such as a keyboard, a mouse, and a video display.

For purposes of this disclosure information handling system 100 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 100 can be a personal computer, a laptop computer, a smart phone, a tablet device or other consumer electronic device, a network server, a network storage device, a switch, a router, or another network communication device, or any other suitable device and may vary in size, shape, performance, functionality, and price. Further, information handling system 100 can include processing resources for executing machine-executable code, such as CPU 102, a programmable logic array (PLA), an embedded device such as a System-on-a-Chip (SoC), or other control logic hardware. Information handling system 100 can also include one or more computer-readable medium for storing machine-executable code, such as software or data.

UEFI BIOS code 172 can be referred to as a firmware image, and the term BIOS is herein used interchangeably with the term firmware image, or simply firmware. In an embodiment, UEFI BIOS 172 can be substantially compliant with one or more revisions of the Unified Extensible Firmware Interface (UEFI) specification. As used herein, the term Extensible Firmware Interface (EFI) is used synonymously with the term UEFI. The UEFI standard replaces the antiquated personal computer BIOS system found in some older information handling systems. However, the term BIOS is often still used to refer to the system firmware. The UEFI specification provides standard interfaces and interoperability guidelines for devices that together make up an information handling system. In particular, the UEFI specification provides a standardized architecture and data structures to manage initialization and configuration of devices, booting of platform resources, and passing of control to the OS. The UEFI specification allows for the extension of platform firmware by loading UEFI driver and UEFI application images. For example, an original equipment manufacturer can include customized or proprietary images to provide enhanced control and management of the information handling system 100. While the techniques disclosed herein are described in the context of a UEFI compliant system, one of skill will appreciate that aspects of the disclosed systems and methods can be implemented at substantially any information handling system having configurable firmware.

UEFI BIOS code 172 includes instructions executable by CPU 102 to initialize and test the hardware components of system 100, and to load a boot loader or an operating system (OS) from a mass storage device. UEFI BIOS code 172 additionally provides an abstraction layer for the hardware, i.e. a consistent way for application programs and operating systems to interact with the keyboard, display, and other input/output devices. When power is first applied to information handling system 100, the system begins a sequence of initialization procedures. During the initialization sequence, also referred to as a boot sequence, components of system 100 are configured and enabled for operation, and device drivers can be installed. Device drivers provide an interface through which other components of the system 100 can communicate with a corresponding device.

The storage capacity of SPI flash device 170 is typically limited to 32 MB or 64 MB of data. However, original equipment manufacturers (OEMs) of information handling systems may desire to provide advanced firmware capabilities, resulting in a BIOS image that is too large to fit in SPI flash device 170. Information handling system can include other non-volatile flash memory devices, in addition to SPI flash device 170. For example, memory 104 can include non-volatile memory devices in addition to dynamic random access memory devices. Such memory is referred to herein as non-volatile dual in-line memory module (NVDIMM) devices. In addition, hard drive 124 can include non-volatile storage elements, referred to as a solid state drive (SSD). For still another example, information handling system 100 can include one or more non-volatile memory express (NVMe) devices. Techniques disclosed herein provide for storing a portion of a BIOS image at one or more non-volatile memory devices in addition to SPI flash device 170.

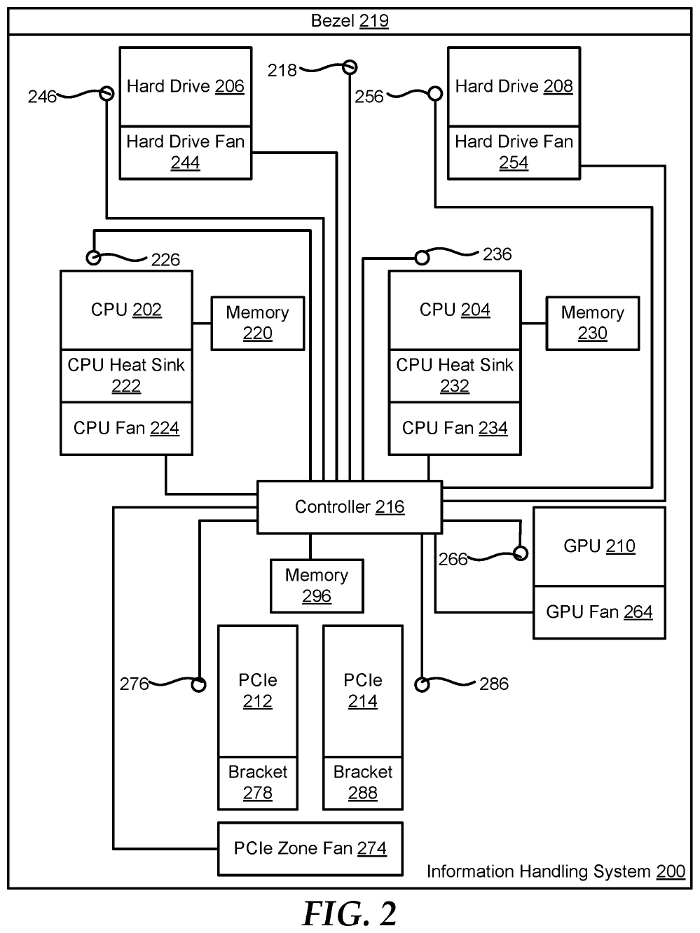

FIG. 2 illustrates a portion of an information handling system 200 according to at least one embodiment of the present disclosure. Information handling system 200 includes CPUs 102 and 104, hard drives 206 and 208, GPU 210, peripheral component interconnect express (PCIe) input/output (I/O) drives 212 and 214, a controller 216, an ambient temperature sensor 218, and a bezel 219. CPU 202 has a memory 220, a heat sink 222, a cooling fan 224, and a temperature sensor 226 in close proximity to the CPU and these components are either in communication with or otherwise associated with the CPU.

CPU 204 has a memory 230, a heat sink 232, a cooling fan 234, and a temperature sensor 236 in close proximity to the CPU and these components are either in communication with or otherwise associated with the CPU. Hard drive 206 has a cooling fan 244, and a temperature sensor 246 in close proximity to the hard drive and these components are either in communication with or otherwise associated with the hard drive. Hard drive 208 has a cooling fan 254, and a temperature sensor 256 in close proximity to the hard drive and these components are either in communication with or otherwise associated with the hard drive. GPU 210 has a cooling fan 264 and a temperature sensor 266 in close proximity to the GPU and these components are either in communication with or otherwise associated with the GPU. PCIe device 212 has a cooling fan 274, a temperature sensor 276, and a bracket 278 in proximity to the PCIe device and these components are either in communication with or otherwise associated with the PCIe device.

PCIe device 214 has cooling fan 274, a temperature sensor 286, and a bracket 288 in close proximity to the PCIe device and these components are either in communication with or otherwise associated with the PCIe device. Controller 216 is in communication with a memory 296. In an example, controller 216 may be any suitable device including, but not limited to, a baseboard management controller. As such, controller 216 may include a processor or may be a processing device. In certain examples, controller 216 may be contained in a single chip configuration or may be multiple controllers located on separate chips. Controller 216 may be a main controller and may control operation of any other controllers within information handling system 200.

During operation of information handling system 200, CPUs 202 and 204, hard drives 206 and 208, GPU 210, and PCIe drives 212 and 214, may be cooled by respective cooling fans 224, 234, 244, 254, 264, and 274. Controller 216 may receive a temperature value from ambient temperature sensor 218, from an external component temperature sensor, from temperature sensors 226, 236, 246, 256, 266, 276, and 286 integrated in or adjacent to respective components, or the like. Controller 216 may adjust a cooling fan speed control profile for control of at least one cooling fan based on the received temperature value. Controller 216 may be configured to generate a different control signal for each cooling fan 224, 234, 244, 254, 264, and 274. The control signal may be a PWM control signal. The controller may also be configured to generate control signals for other system and component cooling fans. Received temperature values may be stored in memory 296 of controller 216 or in a system memory and may be associated with timing parameters indicating a time at which the temperature value was received.

In previous information handling systems, cooling changes or variations mainly rely on temperature sensors and power consumption of the components within the information handling system to control the speed of the cooling fan. Previous information handling system thermal designs usually used open-loop and closed-loop control methods, perform fan control based on the system ambient temperature and device temperature. However, this previous control method was based on the constant system impedance and device thermal resistance measured in development stage. Previous information handling systems did not monitor real-time changes in these characteristics in the whole product life cycle to provide early warning and repair, so as to avoid further thermal issues happen. In these previous information handling systems, cooling capacity degradation associated within individual components or the entire system are not monitor. As such, previous information handling systems, would not provide warnings and correction suggestions to users of the information handling system to overcome potential risks for cooling degradations.

In the life cycle of information handling system 200, the system impedance and component thermal resistance may often change due to various reasons or cooling degradations. In an example, cooling degradations may include, but are not limited to, dust adhering to the surface or bezel 219 of the information handling system in a rugged environment, dust buildup on heat sink 222 or 232, dust building up on bracket 278 or 288, silicone grease for one of CPUs 202 or 204, or CPU 210 may age during long-term use, and incorrect cabling may cause greater air impedance. As a result, the cooling efficiency within information handling system may be reduced, and the information handling system may even further overheat and cannot be used normally.

Information handling system 200 may be improved by diagnosing multiple cooling capability degradations within the information handling system. In an example, the detection of cooling capability degradations may be performed in a factory to detect potential thermal issues created during assembly of information handling system 200, in use by an individual associated with the information handling system to determine thermal faults within the information handling system. As described below, components, such as controller 216, within information handling system 200 may improve the information handling system by implementing cooling capacity degradation diagnosis solution.

Controller 216 may improve information handling system 200 by calculating and monitoring thermal resistance and power consumption changes in the different components 202-214 and by monitoring temperature sensors 218, 226, 236, 246, 256, 266, 276, and 286, and other parameters within the information handling system. Controller 216 may also detect multiple events that may cause cooling degradation within information handling system 200 including, but not limited to, aging of chip silicone grease, a dust adhesion rate on bezel 219, heat sinks 222 and 224, and brackets 278 and 288. Controller 216 may further improve information handling system 200 by locating the location where cooling capacity degradation occurs in the computer system. Controller 216 may also provide users of information handling system 200 with warning messages and correction suggestions after the detection the cooling capacity degradation in the information handling system.

In an example, a baseline of cooling conditions within information handling system 200 may be calculated at any suitable time and for the system as whole or for individual components within the information handling system. For example, the baseline cooling conditions may be calculated during a development phase of information handling system 200, during a manufacturing phase, during an initial power on of the information handling system, or the like. During the development phase, the baseline cooling conditions may be calculated based on simulations and collected test data. During the factory phase of information handling system 200, the baseline cooling conditions may be calculating based on cooling data collected during tests run in the information handling system. During the initial power on, the baseline cooling conditions may be calculated based on customer environment data during first boot of information handling system 200. In an example, controller 216 may utilize the baseline cooling conditions calculated during any of the different phases of information handling system 200 to help debug degradation issues at any of the phases.

In an example, the baseline cooling conditions may be stored in memory 296 or any other memory within information handling system 200. Also, during each of the baseline phases, one or more thermal resistance versus fan PWM curves may be created and stored within memory 296. In certain examples, these curves may be created for any suitable key devices in information handling system 200 including, but not limited to, CPUs 202 and 204, hard drives 206 and 208, GPU 210 and PCIe devices 212 and 214. In an example, the data of the curves may be utilized by controller 216 as references of healthy platforms without cooling performance degradation issues, such as dust accumulation, thermal grease aging, or the like. Data for typical use cases of information may be collected and stored. The data may include any suitable data including, but not limited to, data sets of workload power, data sets of fan PWM signals, data sets of ambient temperatures, data sets of information handling system 200 temperatures, and data sets of individual component or device temperatures.

During operation of information handling system 200, controller 216 may perform one or more operations to collect data within and to monitor a health status of the information handling system. For example, controller 216 may monitor and analyze real-time data as compared to historical or baseline data. Controller 216 may also evaluate data generated or collected during the analysis to locate a location for a cooling degradation issue. In an example, the location for the cooling degradation issue may be the entire information handling system 200 or may be isolated to a particular device, such as one of CPUs 202 and 204, hard drives 206 and 208, GPU 210 and PCIe devices 212 and 214. In response to one or more cooling degradation issues being detecting and the location being identified, controller 216 may perform a follow up operation including providing a warning message, performing a deep diagnostic analysis, providing a repair and protect message, and providing the data to a cloud server for data mining.

In certain examples one or more of temperature sensors 218, 226, 236, 246, 256, 266, 276, and 286 and cooling fans 224, 234, 244, 254, 264, and 274 may exist within previous information handling system, such that controller 216 may utilize temperature sensors and cooling fans that already designed within an information handling system to determine cooling degradation issues. Based on the data from one or more of temperature sensors 218, 226, 236, 246, 256, 266, 276, and 286 and cooling fans 224, 234, 244, 254, 264, and 274, controller 216 may calculate changes in an impedance and thermal resistance of information handling system 200, and compare the changes to historical data for the information handling system. Controller 216 may utilize the comparison between real-time changes and historical data to evaluate the health of the system cooling within information handling system 200.

In an example, controller 216 may calculate the thermal resistance (R) for a specific device or component, such as CPU 202, based on equation 1 below:

R=(T_CPU_Sensor−T_CPU_Inlet_AMBIENT)/Power_CPU EQ. 1

In equation 1 above, T_CPU_Sensor may be the temperature value received from temperature sensor 226. Power_CPU is an amount of power consumed by CPU 202 and controller 216 may receive this data from the CPU itself. In an example, T_CPU_Inlet_Ambient may represent the ambient temperature at the air inlet for CPU 202 and controller may calculate this value based on any suitable data collected within information handling system 200. In an example, controller 216 may calculate T_CPU_Inlet_Ambient equation 2 below:

T_CPU_Inlet_Ambient,=T_Ambient+T_Preheat EQ. 2

T_Ambient may be a temperature value for the ambient temperature received within information handling system 200, and this temperature value may be received from any suitable device, such as temperature sensor 218. In an example, the variable T_Preheat may represent an increase airflow temperature from the ambient temperature until the airflow reaches CPU 202. Controller 216 may calculate T_Preheat based on equation 3 below:

T_Preheat=(Power_DriveBay+Power_Fan)/FanAirflow EQ. 3

Power_DriveBay may be the amount of power consumed by the hard drives, such as hard drives 206 and 208, within the drive bay of information handling system 200. In an example, controller 216 may received the power consumption of hard drives 206 and 206 directly from the hard drives. While cooling fan 224 is illustrated on a side of CPU 202 opposite of hard drive 206, the cooling fan may be located in between the CPU and the hard drive without varying from the scope of this disclosure. Power_Fan may be the amount of power consumed by cooling fan 224 associated with CPU 202. In an example, controller 216 may receive the power consumed by cooling fan 224 as part of the data provided by the cooling fan. FanAirflow may represent an amount of airflow provided by cooling fan 224 and controller 216 may calculate this airflow based on equation 4 below:

FanAirflow=Specific_Heat*Density*FanCFM EQ. 4

Specific_Heat and density represent may represent airflow properties within information handling system 200. In an example, FanCFM may represent the airflow through cooling fan 224 and this amount of airflow may be determined based on any suitable data. For example, controller 216 may determine FanCFM based on both PWM value settings of cooling fan 224 and a FanP-Q curve for the cooling fan. While equations 1-4 above have been illustrated for the thermal resistance (R) of CPU 202, controller 216 may utilize similar equations to calculate the thermal resistance of any component with information handling system including, but not limited to, CPU 204, hard drives 206 and 208, GPU 210, and PCIe drives 212 and 214.

As described above, controller may collect data sets associated with entire information handling system 200 or with individual components. In an example, the data sets may include, but are not limited to, a workload power, fan PWM, ambient temp, and device temp. In certain examples, controller 216 may collect these data sets during any suitable point, such as when a typical use case appears in information handling system 200, when customer usage would not impact the data, or the like. Customer usage may not impact the data sets when information handling system 200 initiates a predefined a scenario, such as the workload during the starting of the information handling system, during idle time period, other phases of information handling system, or the like.

In response to controller 216 calculating the thermal resistance (R) for a specific component, such as CPU 202, the controller may analyze the change in device thermal resistance (R) at the typical workload or fan PWM in the baseline database. Controller 216 may compare the calculated thermal resistance (R) with a thermal resistance (R) stored within a database. In an example, this comparison may be iteratively performed to create a thermal resistance (R) model for the entire information handling system 200 or for a particular device. Based on R model, controller 216 may determine a percentage of area blocked and a location of the degradation issue with respect to a device or position, such as CPUs 202 and 204, hard drives 206 and 208, GPU 210, PCIe drives 212 and 214, brackets 278 and 288, and one or more air ducts within information handling system 200.

Continuing with the example above of CPU 202, controller 216 may calculate FanAirflow for cooling fan 224 via any suitable manner. In an example, controller 216 may determine the FanAirflow based on an intersection point of a Fan P-Q curve where a corresponding fan PWM intersects with a healthy system impedance curve which is embedded in the algorithm database. In response to the thermal resistance R being determined, controller 216 may perform any suitable operations to determine an estimated blocked area ratio for the location associated with the cooling degradation issue. For example, controller 216 may map the thermal resistance R with a fan PWM curve, and the resulting point of the fan PWM curve may correspond to a blockage area ratio.

In response to a blockage area ratio being determined, controller 216 may utilize the determined blockage area ratio to determine another FanCFM value for cooling fan 224. Controller 216 may then utilize this FanCFM value to calculate another thermal resistance R for CPU 202. In certain examples, this iterative process may continue a predetermined number of time to meet accuracy by relocating the intersect point of the system impedance curve based on the estimated blocked area ratio. In an example, the impedance curves at different blocked area ratios may be embedded in a database, such as a database within memory 296.

In an example, if information handling system 200 and each of its components has a healthy status, controller 216 may estimate or determine that the blocked area ratio of a calculated thermal resistance R equates to no dust associated with the component, such as CPU 202. In an example, the nonzero blockage area associated with CPU 202 may indicate a percentage of dust buildup on heat sink 222. In response to the blocked area ration being a nonzero value, controller 216, executing firmware, may generate and display a system event log (SEL) to suggest service to clean the dust buildup on heat sink 222 within information handling system 200. In response to the block area ration being nonzero, controller 216 may also decrease the CPU T_target to prevent CPU 202 from over heating when the workload of CPU 202 steeply increases after a cooling performance degradation for heat sink 222. In an example, controller 216 decreasing CPU T_target may in turn trigger fan speed control, increase a fan PWM baseline value for CPU 202, or the like.

In certain examples, for cooling degradation issues associated other devices, such as CPU and 204, hard drives 206 and 208, GPU 210, and PCIe drives 212 and 214, controller 216 may determine the location of the cooling degradation in any suitable manner. For example, controller 216 may locate the cooling degradation by reading or receiving changes in the temperature of the GPU 210 via sensor 266, or may receive temperature changes in one or both of PCIe cards 212 and 214. In an example, if dust blocks bracket 278 of PCIe 212, lower airflow would go through PCIe 212 and the increased impedance would enable higher airflow go through its adjacent card PCIe 214, such that the temperature of PCIe 212 may increase and the temperature of PCIe 214 may decrease.

In an example, dust may randomly attach to different portions front bezel 219, which in turn may generate blockage anywhere in the bezel. In response to blockage within bezel 219, controller 216 may determine an increase in the PWM values in all fan zones of information handling system 200 while the readings of all the monitored temperature sensors 218, 226, 236, 246, 256, 266, 276, and 286 may barely decrease. This small decrease in temperature may occur at a low ambient temperature with low workload of the components, such as CPUs 202 and 204, hard drives 206 and 208, GPU 210, and PCIe devices 212 and 214. In an example, the increase in the PWM of all cooling fans, such as cooling fans 224, 234,244, 254, 264, and 274, without a decrease in temperature may indicate that almost all the key devices are impacted by the blocked bezel 219.

In certain examples, thermal impedance changes within information handling system 200 may be caused by the cables attached to the rear side of the information handling system. In this situation, controller 216 may detect different thermal resistance R changes at different portions of information handling system 200. For example, CPUs 202 and 204 and GPU 210 may experience an increase in PWM signals for the respective cooling fans 224, 234, and 264, while cooling fans within cooling zone 274 associated with PCIe drive 212 and 214 may not have an increase in PWM signals. In an example, these differences in PWM signals may be based on cables in the rear of information handling system may be located along the sides of the rear surface, which in turn may restrict airflow to CPUs 202 and 204 and GPU 210 while not affecting airflow to PCIe drives 212 and 214.

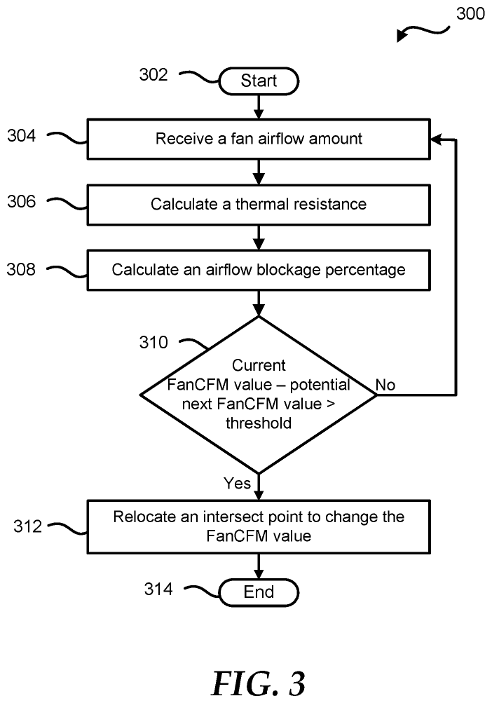

FIG. 3 illustrates a flow diagram of a method 300 for calculating an airflow blockage percentage within an information handling system according to at least one embodiment of the present disclosure, starting at block 302. It will be readily appreciated that not every method step set forth in this flow diagram is always necessary, and that certain steps of the methods may be combined, performed simultaneously, in a different order, or perhaps omitted, without varying from the scope of the disclosure. FIG. 3 may be employed in whole, or in part, by controller 216 of FIG. 2, or any other type of controller, device, module, processor, or any combination thereof, operable to employ all, or portions of, the method of FIG. 3.

At block 304, a fan airflow amount is received. In an example, the fan airflow amount may be associated with any particular component within the information handling system, such as a CPU, hard drive, GPU, PCIe device, or the like. The fan airflow amount may be determined based on any suitable data including, but not limited to, data from a P-Q curve. In an example, an exemplary P-Q curve is illustrated in FIG. 3.

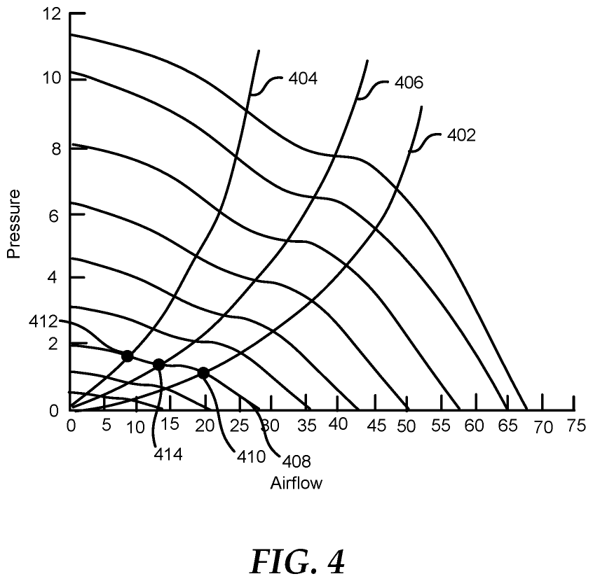

FIG. 4 illustrates multiple waveforms of a P-Q curve associated with a cooling fan within an information handling system according to at least one embodiment of the present disclosure. In an example, each of curves 402, 404, and 406 may be associated with an airflow impedance of a particular component, such as CPU 202 of FIG. 2, based on different amounts of blockage for that component. For example, curve 402 may be the airflow impedance curve for the component when there is not blockage. Curve 404 may be the airflow impedance with a large amount of blockage, and curve 406 may be the airflow impedance with a moderate amount of blockage.

In an example, the curves from the vertical axis to the horizontal axis may be different P-Q curves and each curve may be associated with a different PWM set point for the cooling fan of the component. For example curve 408 may be the P-Q curve for the cooling fan, such as cooling fan 224 of FIG. 2, based on a current set point of the PWM signal for the cooling fan. In certain examples, the intersection of a current airflow resistance curve and P-Q curve for the current PWM signal may provide a FanCFM value, such as point 410 at the intersection of airflow impedance curve 402 and P-Q curve 408, point 412 at the intersection of airflow impedance curve 404 and P-Q curve 408, and point 414 at the intersection of airflow impedance curve 406 and P-Q curve 408. In an example, the FanCFM value for the intersection point of the current airflow impedance and the current P-Q curve, such as at point 410, may be provided as the fan airflow amount at block 304 of FIG. 3.

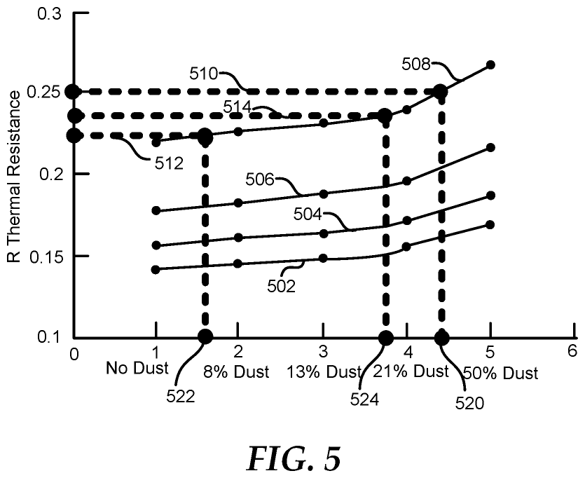

Referring back to FIG. 3, at block 306, a thermal resistance for the component is calculated. In an example, the thermal resistance may be calculated by any suitable manner. For example, the thermal resistance may be calculated utilizing equations 1-4 described above with respect to FIG. 2. At block 308, an airflow blockage percentage is calculated. The airflow blockage percentage may be determined based on any suitable data including, but not limited to, data mapping the current thermal resistance with the current PWM signal for the cooling fan. In an example, the mapping of the current thermal resistance with the current PWM signal for the cooling fan is illustrated in FIG. 5.

FIG. 5 illustrates multiple curves 502, 504, 506, and 508 representing a thermal resistance in cooling fans with respect to a current blockage percentage for a given PWM signal set point for a cooling fan within an information handling system according to at least one embodiment of the present disclosure. As shown by curves 502, 504, 506, and 508, the thermal resistance increases for the same PWM signal set point as a blockage percentage increases. In certain examples, different calculated thermal resistances may be represented by horizontal dashed lines 510, 512, and 514, and respective blockage percentages 520, 522, and 524 may be calculated or determined based on a current PWM signal curve. In an example, thermal resistance 510 may be calculated in block 306 and as a result blockage percentage 520 may be calculated or determined in block 308 based on the intersection of dashed line 510 and curve 508. In this example, the calculated blockage percentage 520 may be utilized to determine a new airflow impedance curve, such as airflow impedance curve 404 in FIG. 4. This new impedance curve may be utilized at block 304 as described below.

Referring back to FIG. 3, a determination is made whether a difference between a current FanCFM value and a potential next FanCFM, is greater than a threshold percentage. If the difference is greater than the threshold, the flow continues at block 312. At block 312, the FanCFM value substituted by relocating the intersect point of the system impedance curve, and the flow ends at block 314.

If the difference is not greater than the threshold, the flow continues as stated above at block 304 and the fan airflow amount is calculated based on a new airflow impedance curve identified by the most recent blockage percentage. In an example, the block percentage 520 may identify airflow impedance curve 404, which in turn may provide FanCFM 412 in FIG. 4 at block 304 of FIG. 3. Then based on the new airflow amount, a new thermal resistance, such as thermal resistance 512 in FIG. 5, may be calculated at block 306 in FIG. 3. At block 306, the new thermal resistance may be utilized to calculate a new blockage percentage 522 in FIG. 5, and the flow continues at stated above at block 310. If blockage percentage 522 is below the threshold, the blockage percentage may identify airflow impedance curve 406 in FIG. 4 as the new airflow impedance curve. As described above, the airflow impedance curve 406 may identify a FanCFM point 404 in FIG. 4 to be determined in block 304 of FIG. 3. This new airflow amount is used to calculate a thermal resistance, such as thermal resistance 514 in FIG. 5, which in turn may be utilized to calculate a new blockage area 524. In certain examples, this iterative process may continued until the difference between a current FanCFM value and a potential next Fan CFM value exceeds the threshold amount in block 310 of FIG. 3, so that a user is provided with an indication of the blockage percentage at block 312, and the flow ends at block 314.

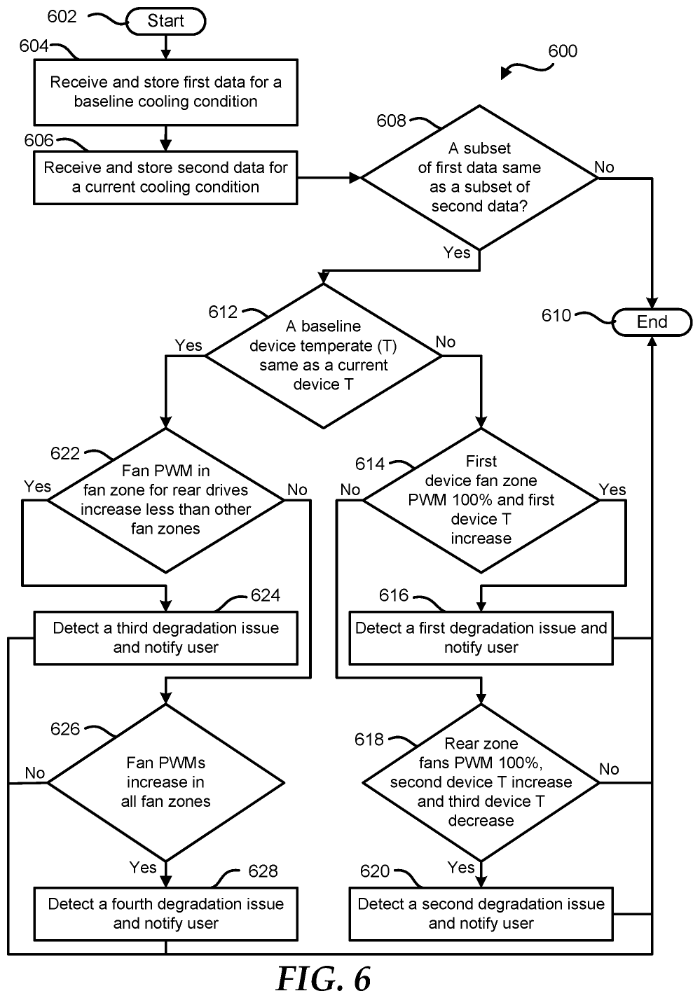

FIG. 6 illustrates a flow diagram of a method 600 for determining one or more cooling degradation issues within an information handling system according to at least one embodiment of the present disclosure, starting at block 602. It will be readily appreciated that not every method step set forth in this flow diagram is always necessary, and that certain steps of the methods may be combined, performed simultaneously, in a different order, or perhaps omitted, without varying from the scope of the disclosure. FIG. 6 may be employed in whole, or in part, controller 216 of FIG. 2, or any other type of controller, device, module, processor, or any combination thereof, operable to employ all, or portions of, the method of FIG. 6.

At block 604, first data for a baseline cooling condition is received and stored. In an example, the first data may be stored in any suitable memory of the information handling system. In certain examples, the baseline cooling condition may be associated with an entire information handling system or with individual components within the information handling system, and the cooling conditions may include any suitable data including, but not limited to, PWM signals and airflow amounts for multiple cooling fans, temperatures from multiple temperature sensors, and power consumption from multiple components. At block 606, second data for a current cooling condition is received and stored. In an example, the second data from include substantially the same type of data as the first data.

At block 608, a determination is made whether a subset of the first data is substantially similar to a subset of the second data. In an example, the subset of first data may include a baseline power value of a component and a baseline ambient temperature value. Similarly, the subset of second data may include a current power value of the component and a current ambient temperature value. In response to the subsets of data not being substantially equal, the flow ends at block 610.

In response to the subsets of data being substantially equal, a determination is made whether a baseline temperature for a device is substantially similar to a current temperature of the device at block 612. In response to the baseline temperature for the device not being the same as the current temperature of the device, a determination is made whether a fan zone of the device is at a hundred percent PWM and the temperature of the device has increased at block 614. If both the fan zone of the device is at a hundred percent PWM and the temperature of the device has increased, a first degradation issue is detected and a user of the information handling notified of the first degradation issue at block 616, and the flow ends at block 610. In an example, the first degradation issue may a buildup of dust on the heat sink of the device.

If the fan zone of the device is not at a hundred percent PWM or the temperature of the device has not increased, a determination is made whether a rear fan zone is at a hundred percent PWM, a second device temperature has increased, and a third device temperature has decrease at block 618. If so, a second degradation issue is detected and a user of the information handling notified of the second degradation issue at block 618 and the low end at block 610. Otherwise, the flow ends at block 610. In an example, the second degradation issue may a buildup of a bracket of the second device.

If at block 612, the baseline temperature for the device is the same as the current temperature of the device, a determination is made whether a fan PWM in a fan zone for rear drives has increased less than the fan PWMs in other zones at block 622. If both the fan PWM in the fan zone for rear drives has increased less than the fan PWMs in other zones, a third degradation issue is detected and a user of the information handling notified of the third degradation issue at block 624, and the flow ends at block 610. In an example, the third degradation issue may be a disorder of cables in the rear of the information handling system.

If the fan PWM in the fan zone for rear drives has not increased less than the fan PWMs in other zones, a determination is made whether fan PWMs have increase in all fan PWMs in all fan zones of the information at block 626. If so, a fourth degradation issue is detected and a user of the information handling notified of the fourth degradation issue at block 628, and the flow ends at block 610. Otherwise, the flow ends at block 610. In an example, the fourth degradation issue may a buildup of dust on a front bezel of the information handling system.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. An information handling system comprising:
a memory to store data associated with a plurality of cooling fans, a plurality of temperature sensors, and a plurality of components within the information handling system; and
a processor to communicate with the memory, the processor to:
store a first set of data for a baseline cooling condition within the information handling system, wherein the first set of data is stored in the memory;
receive a second set of data for a current cooling condition within the information handling system;
determine whether a first subset of data in the first set of data is substantially equal to a second subset of data in the second set of data;
in response to the first subset of data being substantially equal to the second subset of data, determine whether a baseline device temperature is substantially equal to a current device temperature; and
in response to the baseline device temperature not being substantially equal to the current device temperature, the processor to determine a first degradation issue within the information handling system based on cooling fans in a first fan zone for the device operating at full speed, and both the device temperature increases and downstream components temperatures increase.

2. The information handling system of claim 1, wherein the first degradation issue is a buildup of dust on the device heat sink.

3. The information handling system of claim 1, in response to the baseline device temperature not being substantially equal to the current device temperature, the processor further to:
determine a second degradation issue within the information handling system based on cooling fans in a second fan zone for a first and second components are operating at full speed, and a first component temperature increases and a second component temperature decreases.

4. The information handling system of claim 3, wherein the second degradation issue is a buildup of dust on a rear bracket of the first component.

5. The information handling system of claim 3, in response to the baseline device temperature being substantially equal to the current device temperature, the processor further to:
determine a third degradation issue within the information handling system based on pulse width modulated signal values for cooling fans in a third fan zone increase substantially less than pulse width modulated signal values for cooling fans in other fan zones.

6. The information handling system of claim 5, wherein the third degradation issue is a disorder of cables in the rear of the information handling system.

7. The information handling system of claim 5, in response to the baseline device temperature being substantially equal to the current device temperature, the processor further to:
determine a fourth degradation issue within the information handling system based on pulse width modulated signal values all cooling fans in the information handling system increasing at a same amount of power.

8. The information handling system of claim 7, wherein the fourth degradation issue is a buildup of dust a front bezel of the information handling system.

9. A method comprising:
storing, in a memory of an information handling system, data associated with a plurality of cooling fans, a plurality of temperature sensors, and a plurality of components within the information handling system;
storing, by a processor of the information handling system, a first set of data for a baseline cooling condition within the information handling system, wherein the first set of data is stored in the memory;
receiving a second set of data for a current cooling condition within the information handling system;
determining whether a first subset of data in the first set of data is substantially equal to a second subset of data in the second set of data;
in response to the first subset of data being substantially equal to the second subset of data, determining whether a baseline device temperature is substantially equal to a current device temperature; and
in response to the baseline device temperature not being substantially equal to the current device temperature, determining, by the processor, a first degradation issue within the information handling system based on cooling fans in a first fan zone for the device operating at full speed, and both the device temperature increases and downstream components temperatures increase.

10. The method of claim 9, wherein the first degradation issue is a buildup of dust on the first device heat sink.

11. The method of claim 9, in response to the baseline device temperature not being substantially equal to the current device temperature, the method further comprises:
determining a second degradation issue within the information handling system based on cooling fans in a second fan zone for a first and second components are operating at full speed, and a first component temperature increases and a second component temperature decreases.

12. The method of claim 11, wherein the second degradation issue is a buildup of dust on a rear bracket of the first component.

13. The method of claim 11, in response to the baseline device temperature being substantially equal to the current device temperature, the method further comprises:
determining a third degradation issue within the information handling system based on pulse width modulated signal values for cooling fans in a third fan zone increase substantially less than pulse width modulated signal values for cooling fans in other fan zones.

14. The method of claim 13, wherein the third degradation issue is a disorder of cables in the rear of the information handling system.

15. The method of claim 13, in response to the baseline device temperature being substantially equal to the current device temperature, the method further comprises:
determining a fourth degradation issue within the information handling system based on pulse width modulated signal values all cooling fans in the information handling system increasing at a same amount of power.

16. The method of claim 15, wherein the fourth degradation issue is a buildup of dust a front bezel of the information handling system.

17. A method comprising:
receiving, by a processor of an information handling, a fan airflow amount associated with a component of the information handling system, wherein the fan airflow amount is based a current FanCFM value located at an intersection point of a current airflow impedance and a current P-Q curve;
calculating a thermal resistance for the component based on the fan airflow amount;
calculating an airflow blockage percentage based on the calculated thermal resistance;
determining is made whether a difference between the current FanCFM value and a potential next FanCFM value is greater than a threshold percentage; and
in response to the difference being greater than the threshold percentage, relocating a next intersect point of the P-Q curve to determine a new FanCFM value.

18. The method of claim 17, the calculating of the airflow blockage percentage is based on data mapping the thermal resistance with a current PWM signal for a cooling fan.

19. The method of claim 17, in response to the difference not being greater than the threshold percentage, the method further comprises:
receiving, by the processor, a new fan airflow amount associated with the component of the information handling system, wherein the new fan airflow amount is based a new FanCFM value located at a new intersection point of a new airflow impedance and a new P-Q curve;
calculating a new thermal resistance for the component based on the new fan airflow amount;
calculating a new airflow blockage percentage based on the calculated new thermal resistance; and
based on the calculated new thermal resistance, calculating a blockage area associated with the component.

20. The method of claim 17, further comprising:
based on the calculated thermal resistance, calculating a blockage area associated with the component.
